(19) United States
(12) Patent Application Publication
(10) Pub. No.: US 2021/0111663 A1
(43) Pub. Date: Apr. 15, 2021

(54) Magnetic-Floating Field-Assisted Thermionic Solar Cell With Semiconductor Nonvolatile Memories and Rechargeable Batteries

(71) Applicant: James Pan, Glen Burnie, MD (US)

(72) Inventor: James Pan, Glen Burnie, MD (US)

(21) Appl. No.: 16/597,696

(22) Filed: Oct. 9, 2019

(51) Int. Cl. H02S 20/00; H02S 40/38; H01L 31/07; H01L 31/0224

(52) U.S. Cl. CPC H02S 20/00; H01L 31/022441; H01L 31/07; H02S 40/38

(57) ABSTRACT

The present invention is about a magnetic solar cell with a semiconductor memory and battery, capable of achieving higher solar efficiency and energy storage capability. The semiconductor magnetic solar system features the following components: a section of very low work function metal, which is physically “floating” in vacuum, as sustained by magnetic fields, and a section of semiconductor to form an Avalanche Breakdown Schottky Diode, and a memory/battery storage unit with a high work function metal.

### FIELD OF THE INVENTION

The present invention relates generally to a solar cell, and more particularly, to a photovoltaic device used to shield heat from sun lights, and to transfer solar or light energy to electrical energy.

### BACKGROUND OF THE INVENTION

The present invention describes a solar cell with magnetic-floating, vacuum, thermionic emission, and semiconductor devices and mechanisms such as nonvolatile memory and semiconductor diode junction avalanche breakdown to achieve a much higher solar efficiency. The solar efficiency of a conventional semiconductor solar cell (multiple junctions or MOS transistors) is very low because most of the solar radiations are absorbed in the semiconductor bulk regions to produce only heat. For the new device, heat is absorbed and insulated by vacuum—so the solar efficiency can be much higher.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention provides a magnetic-floating solar cell that includes a solar unit to absorb sun lights. The solar unit is surrounded by vacuum for perfect heat insulation, so no heat may be transferred from the magnetic-floating solar unit to any other substances. When temperature rises in the floating solar unit due to lights, thermionic emission causes heated electrons to leave the very low work function metal of the floating solar unit and enter the vacuum. The electric fields help hot electrons tunnel through the thin vacuum and reach the electrodes in the surrounding chamber. These electrodes also form electric fields in the Schottky Diode (which is a metal-semiconductor diode) inside the magnetic-floating solar unit. The field-assisted thermionic emission causes more electrons to be emitted from the magnetic-floating solar unit to the vacuum. The electrons flow through the high work function storage unit or nonvolatile memory, then eventually cool down and flow back to the magnetic-floating solar unit for charge replenishment.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 describes the central magnetic-floating solar unit inside the solar cell for absorption of lights from sun or from other light sources. This center piece is supported by electric-magnetic fields—it is magnetic-floating in vacuum. When light is absorbed in this center piece, heat is generated. The heat can not be transferred through vacuum without interactions of electrons. As the result, the temperature of the magnetic-floating center piece rises, until the hot electrons can be removed. These hot electrons may leave the center piece and tunnel through the vacuum by a process called “Electric Field Assisted Thermionic Emission”. Electric fields from the electrodes in the surrounding chamber sidewalls help the hot electrons tunnel through the thin vacuum, because the metal work function of the metal films in the magnetic-floating center piece is very low—the energy for electrons to be taken out of the metal is low for such low work function metals. Energy for electrons to leave the metal is even lower when electric fields are present.

FIG. 2 shows a solar cell with the central light absorption magnetic-floating unit attached to a region of high work function metals. Hot electrons generated by sun lights in the low work function metal of the magnetic-floating central unit are transferred, first by field-assisted thermionic emission through the surrounding vacuum, then to the high work function metal in a region insulated by dielectrics. In between the high and low work function metals there is a natural electric potential developed—when the energy of the hot electrons is converted to electrical signals, the cooled electrons are sent back to the central unit.

FIG. 3 illustrates a solar cell with the central light absorption magnetic-floating unit, and a semiconductor nonvolatile memory attached. There are semiconductors in between the magnetic-floating central unit and nonvolatile memory to facilitate electron transfer between the regions. FIG. 4 shows the composition of the center magnetic-floating piece for light absorption: low work function metal, magnetic materials, and semiconductors which form a Schottky Diode for high field avalanche breakdown to rapidly generate a large amount of hot electrons.

### DETAILED DESCRIPTION OF THE INVENTION

The present invention will now be described with respect to the accompanying drawings in which like numbered elements represent like parts. The figures provided herewith and the accompanying description of the figures are merely provided for illustrative purposes. One of ordinary skill in the art should realize, based on the instant description, other implementations and methods for fabricating the devices and structures illustrated in the figures and in the following description.

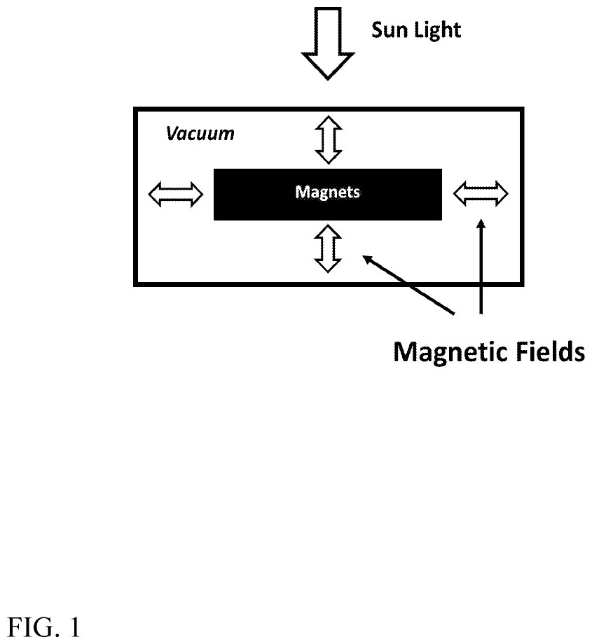

The central magnetic-floating unit described in FIG. 1 absorbs lights through a focal lens above it, and the temperature rises due to the heat from absorbed lights by electrons. Temperature comes from energized electrons. The heat can not be transferred to the surrounding chamber sidewalls because the vacuum blocks the hot electrons. But the electrons may tunnel through the thin vacuum with the electric fields inside the magnetic-floating central unit and across the thin vacuum, generated by the electrodes in the chamber sidewalls. This process is called “Field Assisted Thermionic Emission”.

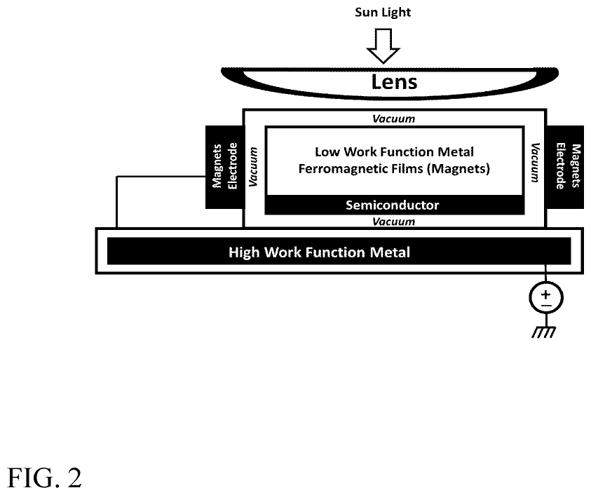

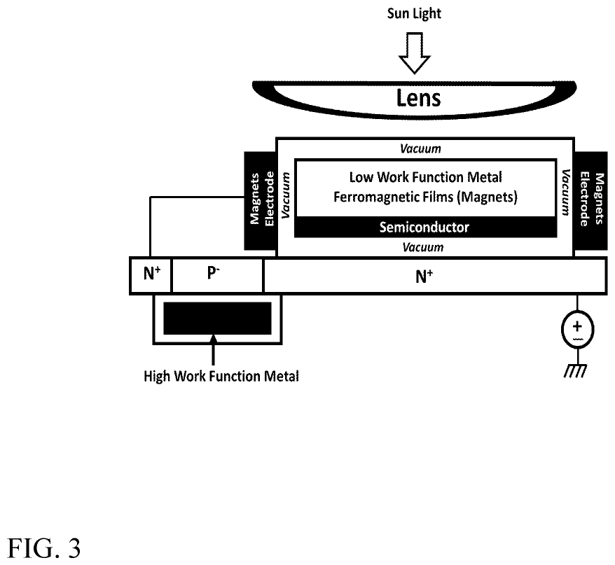

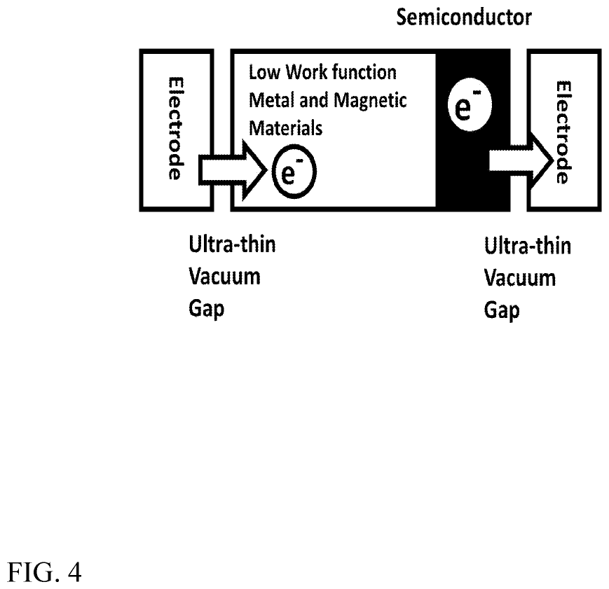

The heated hot electrons leave the center light absorption magnetic-floating unit, pass through the thin vacuum with thermionic emission and enter the electrodes in the sidewalls. There the energy of the electrons is converted to electrical signals, and the temperature cools down. They are transferred to an insulated high work function metal region for charge storage. This is shown in FIG. 2. The high work function region can be the gate region of a semiconductor nonvolatile memory (FLASH memory), as illustrated in FIG. 3. There are n+ and p+ doped semiconductors in between the low work function and high work function metals for transistor operations.

The central light absorption magnetic-floating unit includes magnetic materials, which interact with the magnetic fields from the surrounding magnetic sources in order to keep the center piece floating in vacuum, and low work function metals for light absorption and for emitting hot electrons, and a semiconductor region to form a Schottky Diode, which generates high electrical fields in the metal-semiconductor junction regions while reverse-biased. This causes an avalanche breakdown that generates a large amount of hot electrons to be sent out of the central magnetic-floating unit through electric field-assisted thermionic emission.

Electrons stored in the high work function metal region are eventually transferred back to the low work function metal of the magnetic-floating solar unit through electric field-assisted tunneling mechanisms. This process completes the cycle for electric current flows, and the solar energy is converted to electrical energy with a much better efficiency, because heat can not be generated or transferred beyond the magnetic-floating center piece surrounded by vacuum. Heat in the center piece can be removed only through field-assisted thermionic emission.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e. that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

1. A magnetic-floating solar cell consists of a floating solar unit which is floating in vacuum as supported by magnetic fields, a chamber with magnetic sources and electrodes containing the magnetic-floating solar unit, a semiconductor storage unit, and a system for rechargeable battery.

2. The magnetic-floating solar unit of claim 1, wherein very low work function metal films, ferromagnetic films, and semiconductor layers are bound together to form a region for absorption of sun lights or other lights, which is literally floating in vacuum confined by a chamber, and to form an Avalanche Breakdown Schottky Diode for Field-Assisted Thermionic Emission.

3. The chamber with magnetic sources and electrodes of claim 1, wherein electrodes are built in the sidewalls, in order to generate magnetic fields for keeping the solar unit floating in vacuum, and electric fields for causing field-assisted thermionic emission, and electrons to tunnel through the ultra-thin vacuum in between the magnetic-floating solar unit and the chamber sidewalls.

4. The semiconductor storage unit, and a system for rechargeable battery in claim 1, wherein a high work function metal is used for electron charge storage, surrounded by dielectrics through which thermionic emitted electrons from the magnetic-floating solar unit tunnel to enter the high work function metal, and semiconductors and metals sections connecting the high work function metal region to the magnetic-floating solar unit to form a system of rechargeable battery.
